(19) United States
(12) Patent Application Publication
(10) Pub. No.: US 2007/0158803 A1
(43) Pub. Date: Jul. 12, 2007

(54) Memory packaging structure of mini SD card

(75) Inventor: Ping-Yang Chuang, Taipei City (TW)

Correspondence Address: RABIN & Berdo, PC, 1101 14TH STREET, NW, SUITE 500, WASHINGTON, DC, 20005, US

(73) Assignees: PING-YANG CHUANG, Taipei City (TW); A-DATA TECHNOLOGY CO., LTD., Taipei (TW)

(21) Appl. No.: 11/603,864

(22) Filed: Nov. 24, 2006

(30) Foreign Application Priority Data
Jan. 4, 2006 (TW) 095200170

(51) Int. Cl. H01L 23/02

(52) U.S. Cl. 257/679

(57) ABSTRACT

A memory packaging structure of mini SD card, the main implementation technology thereof comprises: to perform the pin adjustment to the: memory originally employing TSOP (Thin Small Out-Line Package) packaging structure, eliminating the gap of 0.1 mm to 0.2 mm between the memory and the circuit board, thus completely attached to the circuit board; to leave the top end of the mini SD card open to directly expose the top end of the memory on the surface of the mini SD card, reducing the thickness of a layer of coverage; to cover the pins on the both sides of the memory to hind them, wherein applying glue joint between the auxiliary lateral body and memory pins to enhance the attachment.

### BACKGROUND OF THE INVENTION

1. Field of the Invention

The present invention relates to a memory packaging structure of mini SD card, in particular to a packaging structure of TSOP (Thin Small Out-Line Package) memory.

2. Background of the Invention

In order to integrally accelerate the computer process speed, the entire system thereof needs to be enhanced, while memory has always been another focus of attention, whose technology of fabrication similarly determines the performance thereof, and the packaging technology stands for one critical stage in the memory fabrication workflow. Memories employing different packaging technologies also create significant differences in performance. From DIP, TSOP to BGA, continuous development of packaging technology enables memory stride toward goals of high frequency and high speed, and the emergence of new technologies, such as CSP, symbolizes that memory packaging has now entered the CSP era. Each bar of memory used nowadays comprises actually a great amount of integrated circuits, but all these circuits need to be packed together to finish in the end, and this kind of technology for wrapping up integrated circuits is so-called packaging technology. Packaging can also be described as the installing the shell of semiconductor integrated circuit chips, which provides not only functionalities of placement, fixation, sealing, protection and heat transfer enhancement, but acts as a bridge communicating between interior world of the chip and exterior circuits—by means of leading wires, tabs on the chip can be coupled to the leading wires of the packaging shell, and the latter leading wires in turn build connections through leading wires on PCB and other parts. Hence, for many integrated circuit products, packaging technology is one critical stage. In our computer, CPU requires to be strictly packaged, so does memory. For a common memory, the size and appearance the people can see are not the actual size and appearance that memory presents; those tiny black blocks neatly aligned one by one are the results of memory chips after packaging processes. In terms of memory, which is a product mainly based on chips, packaging technology is able to not only guarantee the isolation of chips from exterior world, preventing erosions to chip circuits by dusts in the air causing performance deterioration; but the quality level thereof relates directly to the design and fabrication of printed circuit boards (PCB) coupled with chips, thus deeply influencing the performance and operations of the functions in chips themselves. As such, packaging technology is analogously like a coat of memory, while the performance of memory is typically judged by appearance: the grade gets higher, the value of coat becomes more superior. As for the case of processor, technology of memory also keeps evolving. The contour of grains within memory in peoples hands gradually changes, becoming smaller and finer. Such changes exist not only on appearance, but these new types of chips, compared with earlier generations thereof, are making significant progress in applicable frequencies and electronic features. This accomplishment is brought by the contribution of new memory chip packaging technology. There are various kinds of chip packaging technology, such as DIP, PQFP, TSOP, TSSOP, PGA, BGA, QFP, TQFP, QSOP, SOIC, SOJ, PLCC, WAFERS, wherein all these sophisticated terms can be clearly appreciated upon understanding the history of chip packaging development. In fact, evolutions of chip packaging technology have been undertaking for generations, technical level advances incessantly generation by generation, including closer ratio of chip area and package are, higher applicable frequency, better heat durability, and more number of leading wires, smaller inter-wire gaps, less weight, enhanced reliability as well as strengthened convenience of use and so forth, such transformations can all be witnessed. During 70s in 20 century, it was Dual In-line Package (DIP) that prevailed. DIP packaging at that time could offer features suitable for welding fixed on PCB guiding holes, providing some advantages over TO-type packaging in terms of easier PCB wiring and simpler operations, whose packaging structure forms were many, comprising multi-layer ceramic DIP, single layer DIP, leading wire framework-based DIP etc. However, one momentous index to assess whether a chip packaging technology is advanced or not is the ratio of chip area and package are, which is more desirable if approaching 1. Taking a chip employing 40 I/O leading wires plastic PDIP technology for example, it chip area/package area=(3×3)/(15 24×50)=1:86, which is far from 1. Not hard to see that such package size is larger than chip, illustrating its low packaging efficiency, taking up much effective packaging area. By the 80s, in which TSOP was the most significant item among many second generation packaging technologies appeared, which soon became widely adopted, and so far it still remains its main stream position in memory packaging field. TSOP stands for Thin Small Outline Package, meaning smaller type package. One typical characteristic of TSOP memory package technology is making leading wires over the periphery of a package chip, such as wires are installed on both sides of integrated circuits of SDRAM memory, and wires are installed on four sides of integrated circuits of SGRAM memory. TSOP is suitable for SMT technology to install wiring on PCB. For TSOP package form size, when electronic current significant changes, output voltage disturbance caused will reduce, hence suitable for high frequency applications, easier to operate and providing higher reliability. Improved TSOP technology currently widely used on SDRAM memory fabrication, and quite a many memory manufacturers, e.g. Samsung, Hyundai, Kingston, now employ such technology for memory packaging processes.

Currently for mini SD applications, memory package technology is constrained by mini-SD protocol specification, wherein only packaging structures of WSOP, UTOP, ULGA or die are applicable to reduce the thickness of memory packages, allowing it to be accommodated in the inside of mini SD card. Aforementioned universal packaging structure can reduce the thickness of memory packages, but package procedures thereof are more complicated and cost more, more susceptible to flaws and hence increasing production overhead, which, compared with TSOP packaging structure used inside SDRAM, represents a type of less economical packaging structure. As a result, to reduce production cost of mini SD card, allowing memory to employ TSOP packaging structure without modifying the specification size of universal mini SD cards, is a subject of industrial value and innovative implication.

### SUMMARY OF THE INVENTION

The main purpose of the present invention is to provide a memory which itself is packaged by TSOP, and which, after special processes such as pin adjustment, can be placed into a general mini SD card, substituting the complicated and non-economical memory packaging structure currently used, allowing the production cost of mini SD card to become less by means of reduction of internal memory component cost.

Another purpose of the present invention is to expand the memory capacity by means of applying TSOP packaging structure to memory in the mini SD card, such that the memory capacity of mini SD card becomes bigger, enabling the users of mini SD save expenditure on purchasing extra memory cards, enhancing thus market competitiveness.

Accordingly, the principal technical means of the present invention is to perform pin adjustment to the pins on both sides of the memory fabricated in accordance with TSOP packaging structure, such that the existing gaps between the memory and the circuit board can hence be totally eliminated, pushing the memory lower thus completely attached to the surface on lower layer circuit board; while the top end of the memory being open without any coverage, allowing the mini SD card to reduce the thickness of auxiliary lateral body required for sealing the top end of the memory, then covering (sealing) the pins on both sides of the memory to the height aligned with the memory, in which the gaps between pins and auxiliary lateral bodies can be glued to enhance the attachment, achieving the effect of memory fixation assistance.

### BRIEF DESCRIPTION OF THE DRAWINGS

FIG. 1a shows a side view diagram of the memory employing TSOP packaging structure;

FIG. 1b shows a side view diagram of the memory employing TSOP packaging structure;

FIG. 2 shows a cross-section view diagram of the memory packaging structure embodiment in accordance with the mini SD card of the present invention;

FIG. 3 shows a top view diagram of the memory packaging structure embodiment in accordance with the mini SD card of the present invention; and

FIG. 4 shows a 3D diagram of the memory packaging structure embodiment in accordance with the mini SD card of the present invention.

### DETAILED DESCRIPTION OF PREFERRED EMBODIMENTS

Hereunder the implementations of the present invention will be further discussed with reference to appended drawings and component symbols, enabling the ones skilled in the art being able to practice the present invention upon reading the specification document.

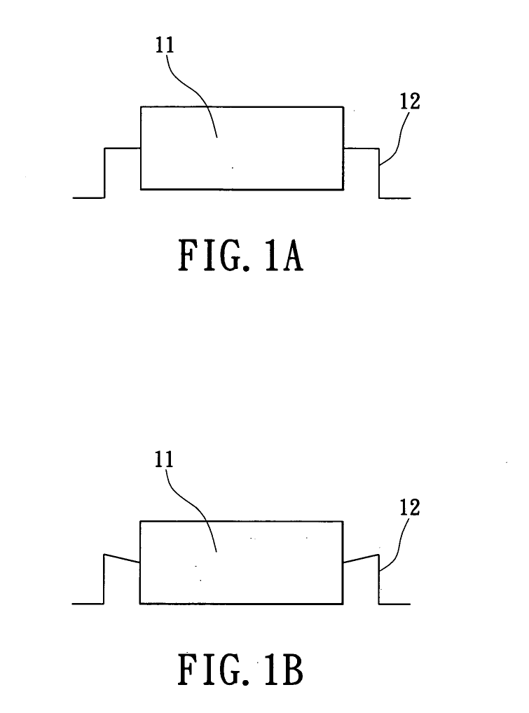

Now refer to FIG. 1, wherein shows a side view diagram of the memory employing TSOP packaging structure. FIG. 1a illustrates a normal TSOP pin connection condition, in which the pin 12 extends from the two sides of the memory 11 and turns downward after a right angle, allowing the pin to support the memory 12 up and to create a gap of 0.2 mm from the surface of printed circuit board. To make the best of the internal space of a mini SD card, allowing the memory 11 utilizing TSOP packaging structure to be placed inside the board with limited space, it is required to perform pin adjustment such that the memory can be completely attached to printed circuit board, as the pin connection condition shown in FIG. 1b. After the pin adjustment on the memory pin 12, the pin connection condition thereof will become first extend upward with an elevated angle from the two sides of the memory 11, then turn downward, such that the gap between the memory 11 and printed circuit board can be eliminated and be fully attached.

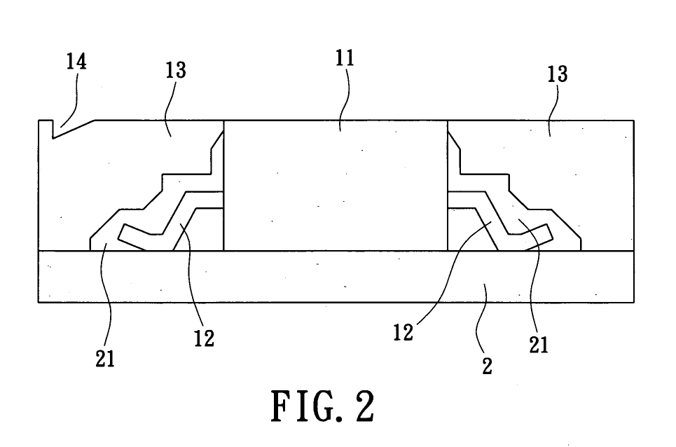

Now refer to FIG. 2, wherein shows a cross-section view diagram of the mini SD card employing TSOP packaging structure. The preferred embodiment of the present invention is provided with a board 2 as a implementation body of the mini SD card, in which on the surface of the board there installed the memory 11, and the auxiliary lateral body 13 for fixing the memory 11 on both sides, wherein the memory 11 being packaged by TSOP packaging structure, and after pin adjustment on the pin 12, the gaps thereof between the board 2 being eliminated and entirely attached to the board 2; the auxiliary lateral body 13 being matched to the pin 12 to extend form the board 2 upward to the same height as the memory 11, in order to clamp fixed the ends on both sides of the memory 2, wherein the surface of said auxiliary lateral body 12 and the one of the memory 11 being aligned in height.

According the above-mentioned discussion and additionally referring again to FIG. 2, in order to apply TSOP packaging structure based memory onto a mini SD card, the major critical approach of the present invention is to leave the top end of the memory 11 uncovered and exposed on the surface of the mini SD card, then use the auxiliary lateral body 13 to cover the pin 12 on the two sides of the memory 11, in order to prevent from being touched by exterior force, and also act as a fixation to the memory 11. Besides, it is possible to apply glue in the gaps 21 between the auxiliary lateral body 13 and the pin 12 to enhance the attachment. Finally, when the mini SD packaging process has been done through this structure, and there installs a groove 14 on the surface of the auxiliary lateral body 13 on one side for helping insert the mini SD card into the device, it is possible to use the groove 14 to apply force and take it out.

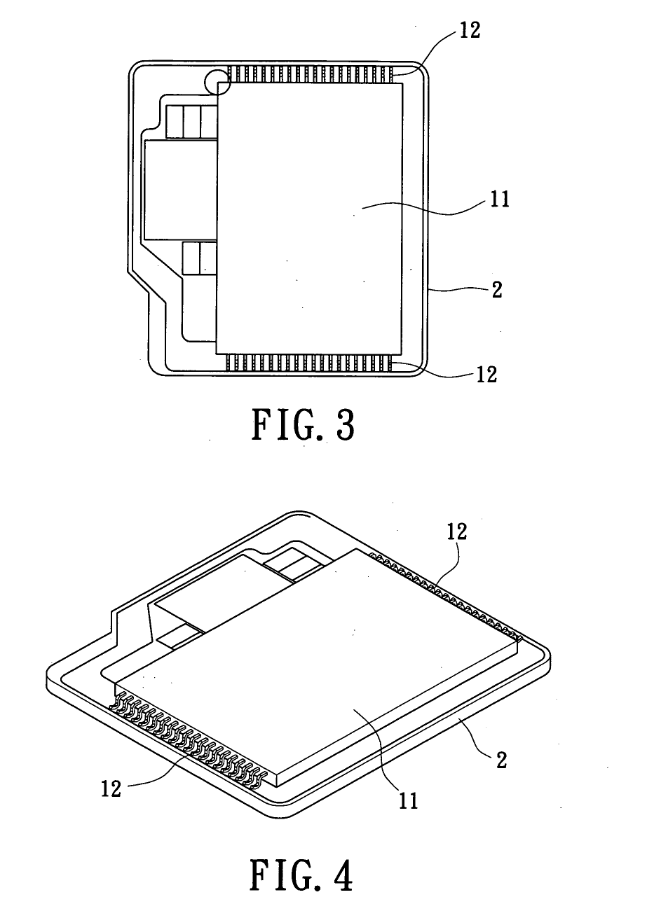

Now refer to FIG. 3, which a top view diagram of the mini SD card is shown. In this drawing, for the memory 11 based on the TSOP packaging structure, the gap between the memory 11 and the board 2 is eliminated by means of the pin adjustment to the pin 12 on both sides, allowing the memory 11 to be closely attached to the surface of the board 2 and thereto fixed.

Refer next to FIG. 4, which illustrates a 3D diagram of mini SD card embodiment extended from FIG. 3. After the pin adjustment of the pin 12, the memory 11 itself is able to attach closely to the surface of the board 2, then cover the pin 12 on two sides of the memory 11 to form the auxiliary lateral body 13, in which it is possible to apply glue joint between the auxiliary lateral body 13 and the pin 12 to enhance the glue strength, thus forming a durable structure (heated glue joint of pins and auxiliary lateral body).

The aforementioned description is merely for the purpose of construing the preferred embodiments of the present invention, not by all means to limit the present invention in any form; accordingly, any modifications or changes made to the present invention under the same inventive spirit should be encompassed within the fields intended to be protected by the present invention.

What is claimed is:

1. A memory packaging structure of mini SD card, comprising:
a board;
a memory having a plurality of pins at two opposing sides, and connected to a surface of the board through the pins, characterized in that:
the memory attached closely to the surface of the board, and two auxiliary lateral body arranged on the two opposing sides for clamping the memory and covering the pins, wherein a surface of the auxiliary lateral body aligned in height to a top end of the memory, such that the top end of the memory directly exposed on an outer surface of the mini SD card.

2. The memory packaging structure of mini SD card of claim 1, wherein an inner layer of the auxiliary lateral body is skew plane.

3. The memory packaging structure of mini SD card of claim 1, wherein the memory is a memory employing the TSOP (Thin Small Out-Line Package) packaging structure.

4. The memory packaging structure of mini SD card of claim 1, wherein an inner layer of the auxiliary lateral body is in a shape of skew plane or step-wise plane or irregular plane, which can be glued with the pins of the memory.
